(19) United States
(12) Patent Application Publication
(10) Pub. No.: US 2007/0063310 A1
(43) Pub. Date: Mar. 22, 2007

(54) A metal fuse for semiconductor devices and methods of manufacturing thereof

(75) Inventor: Shin-Puu Jeng, Hsinchu (TW)

Correspondence Address: BAKER & MCKENZIE;ON BEHALF OF TSMC, 2300 TRAMMELL CROW CENTER, 2001 ROSS AVENUE, SUITE 2300, DALLAS, TX, 75201, US

(73) Assignee: TAIWAN SEMICONDUCTOR MANUFACTURING COMPANY, LTD., Hsinchu (TW)

(21) Appl. No.: 11/162,669

(22) Filed: Sep. 19, 2005

(51) Int. Cl. H01L 29/00

(52) U.S. Cl. 257/529

(57) ABSTRACT

Described is a metal fuse in a semiconductor device that can be readily blown up without compromising device reliability, as well as methods of manufacturing thereof. In one embodiment, a metal fuse structure according to the disclosed principles comprises a semiconductor substrate, and an interconnect layers located on the semiconductor substrate, where the interconnect layer has metal contacts formed through the interconnect layer. In addition, the structure includes a metal fuse formed over the interconnect layer and in electrical contact with the metal contacts. Furthermore, the structure includes a polymeric coating formed over the metal fuse and the interconnect layer, where the polymeric coating is selected to allow radiation to pass therethrough.

### TECHNICAL FIELD

This disclosure relates in general to semiconductor devices, and more particularly to a metal fuse structure for semiconductor devices and fabrication methods thereof.

### BACKGROUND

Metal fuses are used in repairing semiconductor circuits and devices. Often times, the repair process involves breaking, severing, or vaporizing metal fuses with a laser beam. For example, there can be multiple memory and redundant cells within a memory device, and when defective memory cells are detected, metal fuses in redundant cells may be “blown” in order to repair the defective memory cells by isolating functional parts of the circuit(s). Metal fuses in redundant cells may also be opened or blown to re-route circuitry along alternative pathways in the event of a memory cell failure. In addition, it is also common to design and fabricate a generic logic chip having a large number of logic gate interconnects. Subsequently, the chip can be customized to perform the desired circuitry by severing the necessary metal fuses after the final processing steps. For additional information on metal fuses in semiconductor devices, please refer to U.S. Pat. Nos. 6,835,642; 6,753,210; 6,613,612; 6,831,349; and 6,784,516.

Metal fuses are typically formed within dielectric materials such as silicon oxide, fluorinated silicon oxide, or other low-K dielectric materials, and can be manufactured from aluminum, copper, or gold. Within the dielectric material, an opening or “window” is normally defined in order to facilitate penetration of the high-energy laser beam used to vaporize the underlying metal fuse. As feature sizes become smaller, the thickness of the dielectric material causes difficulty in blowing conventional metal fuse structures using known lithographic and etching techniques. One solution is to increase the energy of the laser beam during the blowing process, but this approach often comes at the expense of micro-cracking and device reliability. Therefore, there exists a need to be able to blow metal fuses without compromising the overall device reliability.

### SUMMARY

Described is a metal fuse in a semiconductor device that can be readily blown without compromising device reliability and methods of manufacturing thereof. Integrated circuits are initially formed on a semiconductor substrate, where the integrated circuits can include multiple interconnect layers. Metal fuses are subsequently formed over the interconnect layers. A polymeric layer is then formed over the metal fuses. The polymeric coating allows an external radiation source to penetrate and “blow up” the underlying metal fuses with less energy than typically required by conventional techniques. As a result, when less energy is used, the likelihood of damaging other circuit components decreases, while the likelihood of properly carrying out the blowing process increases.

In one embodiment, a metal fuse structure according to the disclosed principles comprises a semiconductor substrate and an interconnect layer located above the semiconductor substrate, the interconnect layer having metal contacts formed through the interconnect layer. Additionally, the structure includes a metal fuse formed over the interconnect layer and in electrical contact with the metal contacts. Furthermore, the structure includes a polymeric layer formed over the metal fuse, the polymeric layer being selected to have a high transmittance to allow radiation to pass through, and to protect the metal fuse from moisture penetration.

In an embodiment of a method of forming a metal fuse in a semiconductor device, the method includes providing a semiconductor substrate, and forming an interconnect layer above the semiconductor substrate. In such an embodiment, the method also includes forming metal contacts through the interconnect layer. Also, the method includes forming a metal fuse over the interconnect layer and in electrical contact with the metal contacts. Furthermore, this embodiment of the method includes forming a polymeric layer over the metal fuse, the polymeric layer allowing radiation to pass therethrough.

### BRIEF DESCRIPTION

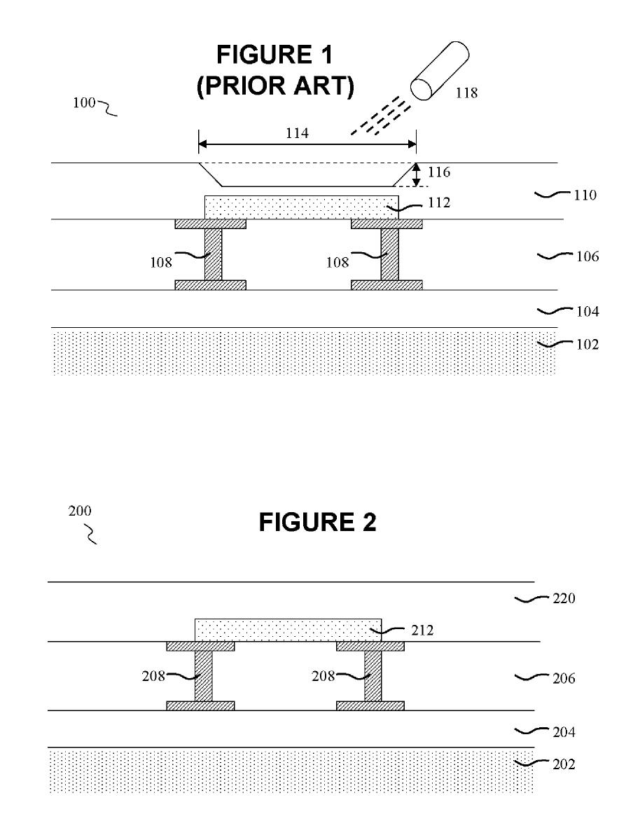

FIG. 1 illustrates a conventional metal fuse structure in a semiconductor device;

FIG. 2 illustrates one embodiment of the presently disclosed metal fuse structure; and

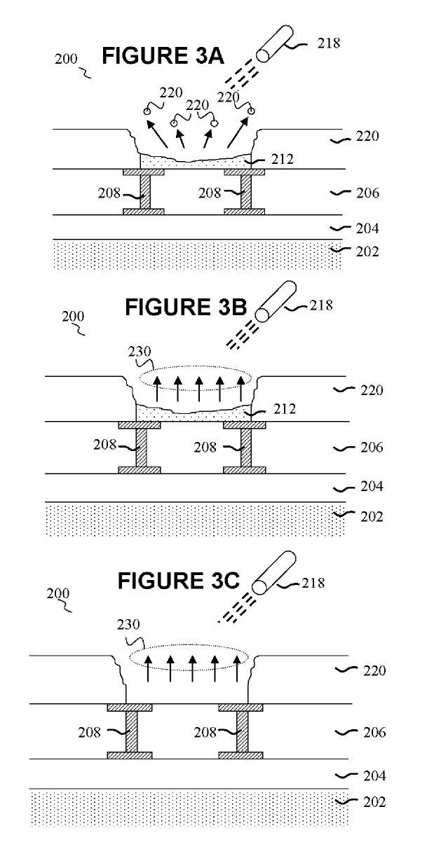

FIGS. 3A-3C illustrate the mechanism behind the presently disclosed metal fuse structure embodiment of FIG. 2.

### DETAILED DESCRIPTION

Initial reference is made to FIG. 1, which illustrates a conventional metal fuse within a semiconductor device 100. A plurality of integrated circuit (IC) interconnect layers 104 are formed on a semiconductor substrate 102 utilizing known materials and methods. The semiconductor substrate 102 is preferably silicon, although silicon-on-insulator (SOI) and gallium arsenide (GaAs) substrates may also be utilized. The various interconnect layers 104 include but are not limited to interlevel metal dielectrics, gate electrodes, interlevel dielectrics, isolation regions, active and passive devices, capacitors and other features. The various interconnect layers 104 may also contain metal contacts (not shown) that electrically connected one layer to another.

An overlying intermetal dielectric (IMD) layer 106 is subsequently formed over the plurality of interconnects 104 using known materials and methods. The IMD layer 106 may include doped or undoped silicon oxide, fluorinated silicon oxide, silicon nitride, silicon oxynitride, low-K dielectric materials, or mixtures thereof. Openings are subsequently defined within the IMD layer 106 and metal contacts 108 are then formed within these openings. The metal contacts 108 provide vertical electrical connections between the underlying interconnect layers 104 and any subsequent overlying layers yet to be fabricated. The metal contacts 108 may be copper, aluminum, gold, titanium, silver or tungsten.

A metal fuse 112 is subsequently formed over and provides an electrical connection for the two metal contacts 108, as illustrated in the figure. A dielectric layer 110 is then formed over the entire wafer that provides added passivation and protection for the metal fuse 112, as well as the underlying materials 102, 104, 106, 108. The dielectric layer 110 may include doped or undoped silicon oxide, fluorinated silicon oxide, silicon nitride, silicon oxynitride, low-K dielectric materials, or mixtures thereof, while the metal fuse 112 is typically copper, aluminum, gold, titanium, silver or tungsten.

A fuse window 114 within the dielectric layer 110 is subsequently defined by known lithographic techniques. After photo-defining the fuse window 114, dielectric materials may be removed from the dielectric layer 110 by known etching processes. The etch process also controls the depth 116 of the fuse window 114. The longer the etch time, the more dielectric material 110 is removed, and less dielectric material 110 will remain over the metal fuse 112. Consequently, a laser beam 118 may be directed through the fuse window 114 to break or vaporize the metal fuse 112 (i.e., “blow”) through the fuse window 114 in order to make repairs to the integrated circuit. In addition to laser beams 118, other sources of photonic radiation, such as a general light source or a broadband lamp, may also be directed through the window 114 to accomplish the repair. Furthermore, electromagnetic radiation, such as electron beam, ion beam, or an electromagnetic source, may also be utilized.

Although an external laser beam 118 may sufficiently penetrate the dielectric material 110 that remains over the metal fuse 112 through the fuse window 114, processing controls can cause uniformity issues across a wafer and lead to failures in blowing some metal fuse 112. For example, deviations during dielectric deposition can give rise to areas of thick and thin dielectric materials 110. The poor uniformity can be further exacerbated during the dielectric etch when the fuse window 114 is formed in the dielectric layer 110. As a result, some fuse windows 114 may be deeper than others. Consequently, metal fuses 112 with larger window depths 116 may be blown at lower laser beam energy 118, while blowing metal fuses with smaller window depths 116 may require higher laser beam energy 118. Accordingly, not all metal fuses 112 will be properly blown.

Reference is now made to FIG. 2, which illustrates one embodiment of a metal fuse structure constructed according to the disclosed principles. FIG. 2 is similar to FIG. 1 in many respects, except that a polymer layer 220 is formed over the metal fuse 212. As illustrated in FIG. 2, interconnect layers 204 are formed on a semiconductor substrate 202 using the same or similar materials and methods as those discussed in the previous figure. An IMD layer 206 and metal contacts 208 are subsequently formed over the interconnect layers 204, also using the same or similar materials and methods discussed with respect to the previous figure. A metal fuse 212 providing electrical connection is subsequently formed over the two metal contacts 208, also as described above.

Instead of forming a layer of dielectric material 110 directly over the metal fuse 112 as illustrated in FIG. 1, the disclosed technique employs a polymeric material 220 deposited or formed over the metal fuse 212. In one embodiment, the polymeric material 220 is polyimide or benzocyclobutene (BCB). In another embodiment, the polymeric material 220 is a photoresist of either positive or negative tone. Although illustrated as rectangular in shape, the polymeric coating 220 can take on a variety of shapes and sizes. If the polymer 220 is processed on a track coater, the coating 220 will have improved uniformity and consistency compared to that of a deposition tool typically used for forming the conventional dielectric layer 110 found in conventional structures. In a preferred embodiment, the polymer 220 has a thickness in the range of 0.5 to 10 micron. Factors that may affect the thickness of the polymeric layer 220 includes but are not limited to the type of polymeric coating employed, the type of radiation source used to ablate the metal fuse(s), and the energy of the radiation source.

Polymers 220 are preferred overlayer materials for metal fuses 212 because polymers 220 have, in general, lower mechanical strength than traditional dielectric material 110 of FIG. 1, such as glass or silicon oxide. Therefore, polymers 220 are easier to crack and remove by an external source of radiation 218, such as a laser beam. Additionally, the transmittance of polyimide 220 decreases with increasing laser energy. In other words, polyimide 220 is transparent at longer wavelengths (900 nm-1500 nm) and becomes more absorbing at shorter wavelengths (500 nm-900 nm). This indicates that polyimide 220 is easier to remove with a laser beam of less than 900 nm wavelength, whereas silicon oxide is more difficult to remove because most dielectric material 110 is transparent at all wavelengths (500 nm-1500 nm).

As a result of the difference in transmittance, laser ablation of the metal fuse 212 through the polymeric coating 220 is easier than through the traditional dielectric material 110. In addition, there is less of a thickness and uniformity concern with polymeric coating 220. The idea is to use an initial laser beam 218 of lower energy to penetrate through the polymeric material 220, followed by a final laser beam 218 of higher energy to blow away the metal fuse 212. The laser beams 218 of different energy may be tuned to specifically remove the type of material involved, such as the polymeric coating 220, and the metal fuse 212. Accordingly, there is little concern for uniformity or fuse windows 114 as a result of the polymer coating 220.

FIGS. 3A-3C illustrate the mechanism behind blowing the metal fuse according to the presently disclosed principles. In FIG. 3A, a laser beam 218 of lower energy may be tuned to specifically penetrate and remove the polymeric coating 220. As the laser beam 218 heats the polymeric coating 220, the polymeric coating 220 slowly transforms from a solid phase to a liquid or gaseous phase. Subsequently, the polymeric coating 220 is expelled in its liquid or gaseous phase. Residual polymer 220 may also be dislodged from the semiconductor device 200. The underlying metal fuse 212 may or may not be substantially damaged depending on the energy of the laser beam 218 and the amount of time.

FIG. 3B illustrates the subsequent step in vaporizing the metal fuse structure, whereby the laser beam 218 is now tuned to output a higher energy level. As a result of the increase in energy, the metal fuse 212 can be heated from a solid phase directly into the vapor phase 230. Eventually, all the metal fuse 212 is ablated into the vapor form 230, and all that remains is a completely blown metal fuse structure 200 as illustrated in FIG. 3C.

Other benefits of the presently disclosed embodiments realized include that by using a polymeric coating 220, there is no longer a need to photo define a fuse window 114. Secondly, there is no longer a need to etch the fuse window 114 to a certain desirable depth 116. The presently disclosed polymeric coating 220 provides a simple and inexpensive technique for blowing metal fuses 212 in semiconductor devices 200, and does not suffer disadvantages associated with conventional techniques. This is because the polymeric coating 220 can be removed by an external radiation source 218 at a lower energy level thereby facilitate vaporizing the underlying metal fuse 212 with minimal resistance. In addition, since the polymeric coating 220 can be performed on a coater track, the coating 220 across a wafer is far more uniform when compared to the uniformity of a conventional dielectric material 110 formed in the typical deposition chamber. Furthermore, other benefits of the coating 220 may also be realized, such as ease of processing, reduced number of processing steps, and expediting the manufacturing process, any one of which can translate into decreased overall manufacturing costs.

It will be appreciated by those of ordinary skill in the art that the invention can be embodied in other specific forms without departing from the spirit or essential character thereof. For example, the metal fuse 212 may take on a variety of shapes and sizes. In one case, the metal fuse 212 may be formed in the shape of a “T”. In other cases, the metal fuse 212 may be formed from or within multi-layers of interconnects. The presently disclosed embodiments are therefore considered in all respects to be illustrative and not restrictive. The scope of the invention is indicated by the appended claims rather than the foregoing description, and all changes that come within the meaning and ranges of equivalents thereof are intended to be embraced therein.

Additionally, the section headings herein are provided for consistency with the suggestions under 37 C.F.R. § 1.77 or otherwise to provide organizational cues. These headings shall not limit or characterize the invention(s) set out in any claims that may issue from this disclosure. Specifically and by way of example, although the headings refer to a “Technical Field,” the claims should not be limited by the language chosen under this heading to describe the so-called technical field. Further, a description of a technology in the “Background” is not to be construed as an admission that technology is prior art to any invention(s) in this disclosure. Neither is the “Summary of the Invention” to be considered as a characterization of the invention(s) set forth in the claims found herein. Furthermore, any reference in this disclosure to “invention” in the singular should not be used to argue that there is only a single point of novelty claimed in this disclosure. Multiple inventions may be set forth according to the limitations of the multiple claims associated with this disclosure, and the claims accordingly define the invention(s), and their equivalents, that are protected thereby. In all instances, the scope of the claims shall be considered on their own merits in light of the specification, but should not be constrained by the headings set forth herein.

What is claimed is:

1. A metal fuse structure in a semiconductor device, comprising:
a semiconductor substrate;
an interconnect layer located above the semiconductor substrate, the interconnect layer having metal contacts formed therein;
at least one metal fuse formed over the interconnect layer and in electrical contact with the metal contacts; and
a polymeric coating formed over the metal fuse and the interconnect layer, the polymeric coating operable to allow radiation to pass therethrough.

2. The metal fuse structure according to claim 1, wherein the polymeric coating is selected from the group consisting of polyimide, benzocyclobutene, and photoresist.

3. The metal fuse structure according to claim 1, wherein the metal fuse is configured to be at least partially ablated by the radiation.

4. The metal fuse structure according to claim 1, wherein the radiation is selected from the group consisting of electromagnetic radiation and photonic radiation.

5. The metal fuse structure according to claim 4, wherein the photonic radiation is selected from the group consisting of a laser, a light source, and a broadband lamp.

6. The metal fuse structure according to claim 4, wherein the electromagnetic radiation is selected from the group consisting of an electron beam, an ion beam, and an electromagnetic source.

7. The metal fuse structure according to claim 1, wherein the polymeric coating has a thickness of in the range from 0.5 to 10 micron.

8. The metal fuse structure according to claim 1, wherein the polymeric coating is operable to be ablated at a lower energy level and the metal fuse is operable to be ablated at a higher energy level.

9. A method of forming a metal fuse in a semiconductor device, the method comprising:
providing a semiconductor substrate;
forming an interconnect layer above the semiconductor substrate;
forming metal contacts through the interconnect layer;
forming at least one metal fuse over the interconnect layer and in electrical contact with the metal contacts; and
forming a polymeric coating over the metal fuse and the interconnect layer, the polymeric coating allowing radiation to pass therethrough.

10. The method according to claim 9, wherein forming a polymeric coating further comprises forming a polyimide coating, a benzocyclobutene coating, or a photoresist coating.

11. The method according to claim 9, wherein forming a metal fuse comprises forming a metal fuse configured to be at least partially ablated by the radiation.

12. The method according to claim 9, wherein forming a polymeric coating comprises forming a polymeric coating configured to allow electromagnetic radiation and photonic radiation to pass therethrough.

13. The method according to claim 12, wherein the photonic radiation is selected from the group consisting of a laser, a light source, and a broadband lamp.

14. The method according to claim 12, wherein the electromagnetic radiation is selected from the group consisting of an electron beam, an ion beam, and an electromagnetic source.

15. The method according to claim 9, wherein forming a polymeric coating further comprises forming a polymeric coating having a thickness in the range from 0.5 to 10 micron.

16. The method according to claim 9, further comprising ablating the polymeric coating at a lower energy level and ablating the metal fuse at a higher energy level.
